(19) United States
(12) Patent Application Publication
(10) Pub. No.: US 2025/0292987 A1
(43) Pub. Date: Sep. 18, 2025

(54) High Brightness X-Ray Source For Semiconductor Metrology

(71) Applicant: KLA Corporation, Milpitas, CA (US)

(72) Inventors: Sergey Zalubovsky, San Jose, CA (US); Benjamin J. Clarke, Milpitas, CA (US)

(21) Appl. No.: 19/050,479

(22) Filed: Feb. 11, 2025

Related U.S. Application Data
(60) Provisional application No. 63/565,005, filed on Mar. 14, 2024.

(51) Int. Cl. H01J 35/10; G01N 23/20008; G01N 23/201; G03F 7/00

(52) U.S. Cl. CPC H01J 35/1017; G01N 23/20008; G01N 23/201; G03F 7/70655; H01J 35/106

(57) ABSTRACT

PROBLEM TO BE SOLVED: To provide a rotary anode X-ray tube capable of achieving a long product life, or capable of increasing thermal input to an anode target. SOLUTION: A rotary anode X-ray tube 1 includes a cathode 60, an anode target 50, a fixed shaft 10, a rotating body 20, and a liquid metal LM. The fixed shaft 10 has a first radial bearing surface S10a and a second radial bearing surface S10b. The rotating body 20 has a third radial bearing surface S21a, a fourth radial bearing surface S21b, and a heat transmission region 21a to which the anode target 50 is fixed and the heat of which is transmitted. In a direction along the central axis A, the center of the heat transmission region 21a is located between a first dynamic bearing B1 and a second dynamic bearing B2.

### CROSS REFERENCE TO RELATED APPLICATION

The present application for patent claims priority under 35 U.S.C. § 119 from U.S. provisional patent application Ser. No. 63/565,005, entitled “High Brightness X-Ray Source for Semiconductor CD-SAXS,” filed Mar. 14, 2024, the subject matter of which is incorporated herein by reference in its entirety.

### TECHNICAL FIELD

The described embodiments relate to X-Ray based metrology systems and methods, and more particularly to methods and systems for improved X-Ray illumination and measurement accuracy.

### BACKGROUND INFORMATION

The various features and multiple structural levels of semiconductor devices such as logic and memory devices are typically fabricated by a sequence of processing steps applied to a specimen. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to measure critical attributes that enable process control to promote higher yield and higher performing devices. Optical and X-Ray metrology techniques offer the potential for high throughput measurements without sample destruction. As a result, measured wafers can be passed to subsequent process steps. This enables calculation of end of line yield correlations, which are vital to understanding line yield. A number of X-Ray metrology based techniques including scatterometry implementations and associated analysis algorithms are used to characterize critical dimensions, film thicknesses, composition and other parameters of nanoscale structures.

As devices (e.g., logic and memory devices) move toward smaller nanometer-scale dimensions, higher aspect ratio, and three dimensional architectures, characterization becomes more difficult. Devices incorporating complex three-dimensional geometry and materials with diverse physical properties contribute to characterization difficulty. For example, modern memory structures are often high-aspect ratio, three-dimensional structures that make it difficult for optical radiation to penetrate to the bottom layers. In addition, the increasing number of parameters required to characterize complex structures, leads to increasing parameter correlation. As a result, the parameters characterizing the target often cannot be reliably decoupled with available measurements. In another example, opaque, high-k materials are increasingly employed in modern semiconductor structures. Optical radiation is often unable to penetrate layers constructed of these materials. As a result, measurements with thin-film scatterometry tools such as ellipsometers or reflectometers are becoming increasingly challenging.

In response, more complex optical tools have been developed. For example, tools with multiple angles of illumination, shorter and broader ranges of illumination wavelengths, and more complete information acquisition from reflected signals (e.g., measuring multiple Mueller matrix elements in addition to the more conventional reflectivity or ellipsometric signals) have been developed. However, these approaches have not reliably overcome fundamental challenges associated with measurement of many advanced targets (e.g., complex 3D structures, structures smaller than 10 nm, structures employing opaque materials) and measurement applications (e.g., line edge roughness and line width roughness measurements).

Atomic force microscopes (AFM) and scanning-tunneling microscopes (STM) are able to achieve atomic resolution, but they can only probe the surface of the specimen. In addition, AFM and STM microscopes require long scanning times. Scanning electron microscopes (SEM) achieve intermediate resolution levels, but are unable to penetrate structures to sufficient depth. Thus, high-aspect ratio holes are not characterized well. In addition, electron beam exposure charges the specimen, which may lead to adverse effects on imaging performance.

To overcome penetration depth issues, traditional imaging techniques such as TEM, SEM, etc., are employed with destructive sample preparation techniques such as focused ion beam (FIB) machining, ion milling, blanket or selective etching, etc. For example, transmission electron microscopes (TEM) achieve high resolution levels and are able to probe arbitrary depths, but TEM requires destructive sectioning of the specimen. Several iterations of material removal and measurement generally provide the information required to measure the critical metrology parameters throughout a three dimensional structure. But, these techniques require sample destruction and lengthy process times. The complexity and time to complete these types of measurements introduces large inaccuracies due to drift of etching and metrology steps. In addition, these techniques require numerous iterations which introduce registration errors.

Another response to recent metrology challenges has been the adoption of X-Ray metrology for measurements including film thickness, critical dimension, composition, strain, surface roughness, line edge roughness, and porosity.

Small-Angle X-Ray Scatterometry (SAXS) systems have shown promise to address challenging measurement applications. Various aspects of the application of SAXS technology to the measurement of critical dimensions (CD-SAXS) and overlay (OVL-SAXS) are described in 1) U.S. Pat. No. 7,929,667 to Zhuang and Fielden, entitled “High-brightness X-Ray metrology,” 2) U.S. Patent Publication No. 2014/0019097 by Bakeman, Shchegrov, Zhao, and Tan, entitled “Model Building And Analysis Engine For Combined X-Ray And Optical Metrology,” 3) U.S. Patent Publication No. 2015/0117610 by Veldman, Bakeman, Shchegrov, and Mieher, entitled “Methods and Apparatus For Measuring Semiconductor Device Overlay Using X-Ray Metrology,” 4) U.S. Patent Publication No. 2016/0202193 by Hench, Shchegrov, and Bakeman, entitled “Measurement System Optimization For X-Ray Based Metrology,” 5) U.S. Patent Publication No. 2017/0167862 by Dziura, Gellineau, and Shchegrov, entitled “X-Ray Metrology For High Aspect Ratio Structures,” and 6) U.S. Patent Publication No. 2018/0106735 by Gellineau, Dziura, Hench, Veldman, and Zalubovsky, entitled “Full Beam Metrology for X-Ray Scatterometry Systems.” The aforementioned patent documents are assigned to KLA-Tencor Corporation, Milpitas, California (USA) and are incorporated herein by reference in their entirety.

Research on CD-SAXS metrology of semiconductor structures is also described in scientific literature. Most research groups have employed high-brightness X-Ray synchrotron sources which are not suitable for use in a semiconductor fabrication facility due to their immense size, cost, etc. One example of such a system is described in the article entitled “Intercomparison between optical and X-Ray scatterometry measurements of FinFET structures” by Lemaillet, Germer, Kline et al., Proc. SPIE, v. 8681, p. 86810Q (2013). More recently, a group at the National Institute of Standards and Technology (NIST) has initiated research employing compact and bright X-Ray sources similar to those described in U.S. Pat. No. 7,929,667. This research is described in an article entitled “X-Ray scattering critical dimensional metrology using a compact X-Ray source for next generation semiconductor devices,” J. Micro/Nanolith. MEMS MOEMS 16(1), 014001 (January-March 2017).

SAXS has also been applied to the characterization of materials and other non-semiconductor related applications. Exemplary systems have been commercialized by several companies, including Xenocs SAS (www.xenocs.com), Bruker Corporation (www.bruker.com), and Rigaku Corporation (www.rigaku.com/en).

Many X-Ray metrology techniques used in semiconductor manufacturing can benefit from high brightness X-Ray sources. For example, critical dimension small angle X-Ray scattering (CD-SAXS) measurements often require long integration times due to the low scattering of certain materials. A high brightness source can improve the throughput of CD-SAXS measurements.

Development efforts in the area of extreme ultraviolet (EUV) lithography are focused on light sources that emit narrowband radiation (e.g., +/−0.1 nm) centered at 13 nanometers (i.e., 92.6 electron volts) at high power levels (e.g., 210 watts of average power at the intermediate focus of the illuminator). Light sources for EUV lithography have been developed using a laser droplet plasma architecture. For example, xenon, tin, and lithium droplet targets operating at pulse repetition frequencies of approximately 100 kHz are pumped by CO2 coherent sources. The realized light is high power (e.g., 210 watts of average power at the intermediate focus of the illuminator is the goal for lithography tools at 13 nanometers). However, the resulting radiation is relatively low energy (92.6 electron volts), which severely limits the utility of these illumination sources in metrology applications. An exemplary system is described in U.S. Pat. No. 7,518,134 to ASML Netherlands B.V., the content of which is incorporated herein by reference in its entirety.

In some examples, X-Ray illumination light is generated by high energy electron beam bombardment of a solid target material, such as rotating anode target material. Rotating anode X-Ray sources are commonly employed for medical imaging and analytical chemistry applications. Numerous versions of rotating anode X-Ray sources are manufactured by companies such as Philips, General Electric, Siemens, and others, for medical imaging applications such as tomography, mammography, angiography, etc. Rigaku Corporation and Bruker Corporation manufacture continuously operated rotating anode sources for analytical chemistry applications such as X-Ray diffraction (XRD), X-Ray Reflectometry (XRR), small angle X-Ray scatterometry (SAXS), wide angle X-Ray scatterometry (WAXS), etc.

Rotating anode targets enable more effective heat removal from the anode material compared to stationary anode targets. Continuously moving the location of electron beam impingement on the anode surface enables more effective cooling via a combination of conductive and convective heat dissipation that decreases focal spot impact temperature and improves X-Ray tube power loading capability. A typical rotating anode source rotates anode material at 5,000 revolutions per minute, or higher. The linear speed of the anode material at the focal spot location may be 25 meters/second, or higher.

Improvements directed toward increased anode heat dissipation and thermal conductivity have been proposed. For example, the FR-X model X-Ray sources manufactured by Rigaku Corporation (Japan) and the TXS model X-Ray sources manufactured by Bruker AXS GmbH (Germany) employ water cooling to dissipate heat generated at the anode.

U.S. Pat. No. 9,715,989 describes an anode structure with high thermal conductivity diamond layers. U.S. Pat. No. 8,243,884 describes the use of diamond-metal composite materials to improve heat dissipation. U.S. Pat. No. 7,440,549 describes a rotating anode device that dissipates heat by a heat pipe effect. U.S. Patent Publication No. 2015/0092924 describes a microstructural anode including a high atomic number material embedded in a high thermal conductivity matrix. U.S. Pat. Nos. 9,159,524 and 9,715,989 describe similar diamond-based heat management solutions in the context of stationary anode sources. The contents of the aforementioned U.S. Patents and U.S. Patent Publications are incorporated herein by reference in their entirety.

Despite improved power loading capabilities, rotating anode sources suffer from significant limitations. For example, operating a rotary anode structure at high power loads generates an excessive amount of heat that is not easily dissipated in a high vacuum environment. Microcracks can form on the rotating anode track at the location of interaction between the electron beam and the target material due to repeated thermal cycling at high power load levels. In some examples, a 20-30% drop in emitted X-Ray flux occurs over the course of the first 1,000 hours of operation. Typically, the anode target requires polishing at a maintenance interval of approximately 3,000 hours. The loss of efficiency and scheduled downtime negatively impact the metrology performance and cost of ownership of the rotating anode based X-Ray illumination source.

Increasing the size and rotational speed of the rotating anode structure may increase power load capability, but this approach also introduces mechanical stability issues, e.g., vibration, run-out, etc., that may enlarge the minimum, achievable X-Ray spot size, which results in a highly undesirable loss of brightness.

Future metrology applications present challenges for metrology due to increasingly high resolution requirements, multi-parameter correlation, increasingly complex geometric structures, and increasing use of opaque materials. The adoption of X-Ray metrology for semiconductor applications requires improved X-Ray sources with the highest possible brightness. Rotary anode drive systems with higher speed capability, improved reliability, and reduced contamination are desired.

### SUMMARY

Methods and systems for generating high brightness, X-Ray radiation suitable for high throughput X-Ray metrology from a high speed, rotating anode based X-Ray illumination source are presented herein. The high brightness, X-Ray radiation enables measurements of structural and material characteristics (e.g., material composition, dimensional characteristics of structures and films, etc.) associated with different semiconductor fabrication processes.

In one aspect, a stream of electrons having a landing energy of at least 80 keV and beam power of at least 400 Watts is directed to a rotating anode material structure. The spatial distribution of the electron intensity of the stream of electrons at the location of incidence is elongated in shape. A major axis is aligned with the direction of maximum extent of the spatial distribution and a minor axis is perpendicular to the major axis. The full width half maximum of the electron intensity along the minor axis is 40 micrometers or less. The full width half maximum of the electron intensity along the major axis divided by the full width half maximum of the electron intensity along the minor axis is at least four. The stream of electrons is incident to the rotating anode material surface at a take-off angle of more than three degrees from normal incidence. In some embodiments, the cross-section of the X-Ray radiation extracted over the area of incidence as viewed along the direction of extraction is approximately circular. The X-Ray emission is collected and directed towards a semiconductor specimen and onto a detector to perform X-Ray based metrology on the specimen.

The high landing energy electron beam enables increased power load on the rotating anode material beyond current state of the art rotating anode based X-Ray sources. The high aspect ratio of the electron beam spot incident on the rotating anode material distributes the heat generated by the high landing energy electron beam over a larger area in the radial direction, thus increasing the lifetime of the anode material. The incidence of the electron beam with the anode material at a shallow take-off angle enables the collection of X-Rays from the high aspect ratio X-Ray emission area over a small area projected in the direction of the collected X-Ray beamline. This results in a very bright X-Ray source as viewed from the direction of the collected X-Ray beamline.

Measurements often need long integration times due to the low scattering efficiency of materials comprising many modern semiconductor structures. A high brightness, high power rotating anode X-Ray source improves the throughput of X-Ray based measurements. The high energy nature of X-Ray radiation allows for the penetration of X-Rays through optically opaque thin films, buried structures, high-aspect ratio structures and devices containing many thin film layers of high Z materials, and the wafer substrate. Many X-Ray metrology techniques used in semiconductor manufacturing benefit from a high brightness, reliable X-Ray source.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of an X-Ray metrology system for performing semiconductor measurements including a high brightness rotating anode based X-Ray illumination subsystem in one embodiment.

FIG. 2 is a simplified diagram illustrative of the incidence of an electron beam on anode material as viewed from a direction aligned with electron beam in one embodiment.

FIG. 3 is a simplified diagram illustrative of X-Rays collected from a high aspect ratio electron beam spot as viewed from a direction aligned with the X-Ray beam in one embodiment.

FIG. 4 is a simplified diagram illustrative of a cross-sectional view of an embodiment of a rotating anode subsystem depicted in FIG. 1.

FIG. 5 is a flowchart illustrative of an exemplary method suitable for generating X-Ray emission from a high brightness, high power rotating anode X-Ray source.

### DETAILED DESCRIPTION

Reference will now be made in detail to background examples and some embodiments of the invention, examples of which are illustrated in the accompanying drawings.

Methods and systems employed to measure structural and material characteristics (e.g., material composition, dimensional characteristics of structures and films, etc.) associated with different semiconductor fabrication processes based on X-Ray illumination are presented. More specifically, methods and systems for generating high brightness, X-Ray radiation suitable for high throughput X-Ray metrology from a high speed, rotating anode based X-Ray illumination source are presented herein.

In one aspect, a stream of electrons having a landing energy of at least 80 keV and beam power of at least 400 Watts is directed to a rotating anode material structure. The spatial distribution of the electron intensity of the stream of electrons at the location of incidence, i.e., the cross-section of the electron beam, is elongated in shape. A major axis is aligned with the direction of maximum extent of the spatial distribution of the electron intensity. A minor axis is perpendicular to the major axis. The full width half maximum of the electron intensity along the minor axis is 40 micrometers or less. The full width half maximum of the electron intensity along the major axis divided by the full width half maximum of the electron intensity along the minor axis, i.e., the aspect ratio of the cross-section, is at least four. The stream of electrons is incident to the rotating anode material structure at a take-off angle of more than three degrees from normal incidence. In some embodiments, the cross-section of the X-Ray radiation extracted over the area of incidence as viewed along the direction of extraction is approximately circular. The extracted X-Ray emission is collected and provided to a semiconductor specimen to perform X-Ray based metrology on the specimen.

The high landing energy electron beam increases the power load on the rotating anode material beyond conventional rotating anode based X-Ray sources. The high aspect ratio of the electron beam spot incident on the rotating anode material distributes the heat generated by the high landing energy electron beam over a larger area in the radial direction, thus increasing the lifetime of the anode material. The incidence of the electron beam with the anode material at a shallow take-off angle enables the collection of X-Rays from the high aspect ratio X-Ray emission area over a small area projected in the direction of the collected X-Ray beamline. This results in a very bright X-Ray source as viewed from the direction of the collected X-Ray beamline.

The high energy nature of X-Ray radiation allows for the penetration of X-Rays through optically opaque thin films, buried structures, high-aspect ratio structures and devices containing many thin film layers. Many X-Ray metrology techniques used in semiconductor manufacturing benefit from a high brightness, reliable X-Ray source, e.g., critical dimension small angle X-Ray scattering (CD-SAXS).

Measurements often need long integration times due to the low scattering efficiency of materials comprising many modern semiconductor structures. A high brightness, high power rotating anode X-Ray source improves the throughput of X-Ray based measurements, e.g., CD-SAXS.

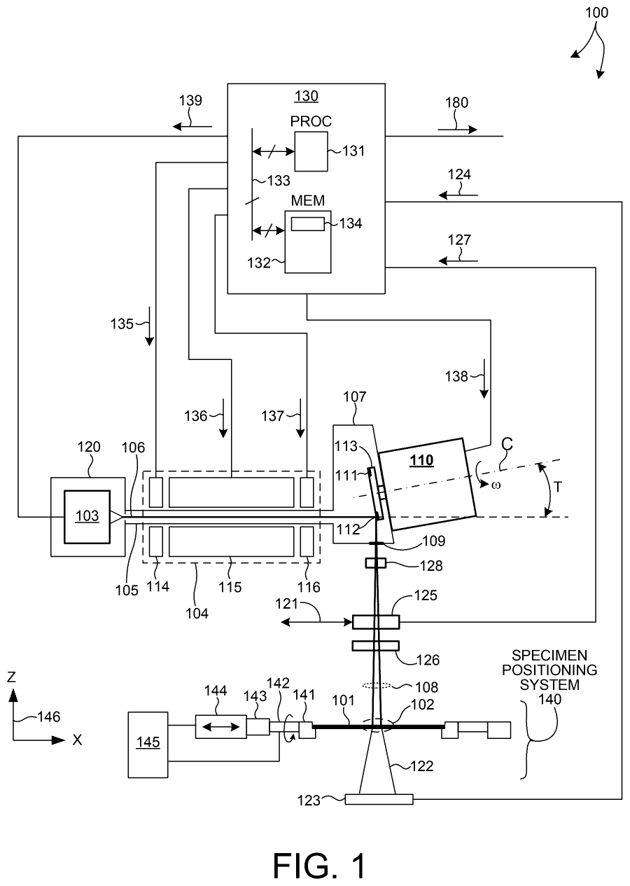

FIG. 1 illustrates an embodiment of an X-Ray based metrology system 100 including a high brightness rotating anode based X-Ray illumination subsystem in one embodiment. By way of non-limiting example, X-Ray metrology system 100 operates in a transmission mode. As depicted in FIG. 1, the X-Ray illumination source includes an electron beam source 103, electron optics 104, and a rotating anode subsystem 110 including an anode material 111 disposed on a rotating platen 113. The rotating anode subsystem 110 includes a rotational actuator that rotates platen 113 about an axis of rotation, A, at an angular velocity, ω. In general, anode material 111 includes any material suitable for emitting X-Rays in response to bombardment by high energy electrons. By way of non-limiting example, anode material 111 includes tungsten, copper, aluminum, a molybdenum alloy such as a titanium, zirconium, and molybdenum (TZM) alloy, a Lanthumum molybdenum alloy, etc.

In the embodiment depicted in FIG. 1, the high brightness X-Ray illumination source includes an electron beam source 103 (e.g., electron gun) configured to generate electron emission from a cathode. In the depicted embodiment, electron beam source 103 generates a stable stream of free electrons 106. The stream of electrons 106 is directed and shaped by electron optics 104 and is incident on anode material 111 supported by rotating platen 113 over an electron illumination spot 112. In some embodiments, the electron beam source 103 is configured to generate a continuous electron beam. In some other embodiments, the electron beam source 103 is configured to generate a pulsed electron beam. In some embodiments, electron beam source 103 includes a Cerium hexaboride (CeB₆) cathode and a bias control grid employed to control the magnitude of the electron current generated by the electron beam source 103. In some other embodiments, electron beam source 103 includes a Lanthanum hexaboride (LaB₆) cathode and a bias control grid employed to control the magnitude of the electron current generated by the electron beam source 103. Thus, for a given beam energy, the bias control grid controls electron beam power.

In the embodiment depicted in FIG. 1, electron beam source 103 is communicatively coupled to computing system 130, and electron beam source 103 is actively controlled based on command signals 139 communicated from computing system 130 to electron beam source 103. In some examples, command signals 139 include an indication of desired electron beam energy to be supplied by electron beam source 103. In response, electron beam source 103 adjusts electron beam energy output to the desired value. In some embodiments, the electron beam source 103 accelerates the stream of focused electrons 106 such that the landing energy of electron beam 106 at incidence with anode material 111 is at least 80 keV. In some embodiments, the landing energy of electron beam 106 at incidence with anode material 111 is greater than 120 keV. In some embodiments, the landing energy of electron beam 106 at incidence with anode material 111 is between 120 keV and 160 keV.

Typically, increasing X-ray source power, reducing e-beam spot size on the target, or both, results in a higher brightness source. It also leads to higher target impact temperature, i.e., instantaneous heating of the material at the electron beam interaction point, and increased surface degradation of the anode material induced by temperature cycling. However, increased electron beam landing energy employed by metrology system 100 increases the depth of penetration of electrons into the surface of the anode target material 111. For example, electron penetration depth for molybdenum is approximately 6 micrometers for 50 kiloelectron volts landing energy and 20 micrometers for 100 kiloelectron volts landing energy.

As a result, the material volume utilized to dissipate generated heat is increased, effectively transitioning from a surface heat load to a volumetric heat load on the target. This leads to lower impact temperature, which enables the operation of the electron beam source at higher power and higher brightness.

The reduction of impact temperature and corresponding scaling in source brightness is much more pronounced at smaller spot sizes, e.g., X-ray source size along the minor axis, B. Heat dissipation is most effective when spot size is smaller or comparable to the typical length scale for heat dissipation. For example, a 100 micrometer spot size enables an increase in beam energy and a 1.5× brightness gain, a 20 micrometer spot size enables an increase in beam energy and a 4× brightness gain, etc. In some embodiments, an electron beam landing energy of 80 kiloelectron volts and a spot size of less than 40 micrometers enables a significant brightness gain over existing X-Ray sources. An additional benefit of higher landing energy is increased Ko yield and hence increased brightness. Thus, by increasing e-beam landing energy while keeping spot size relatively small the brightness of X-rays generated by the rotating anode source is increased with less surface degradation.

In some embodiments, beam power is also controlled, e.g., by a bias control grid, such that the power of electron beam 106 is greater than 400 Watts. In some embodiments, beam power is controlled such that the power of electron beam 106 is greater than 1000 Watts.

Electron optics 104 direct and focus the stream of electrons 106 toward the anode material 111. Electron optics 104 includes suitable electromagnets, permanent magnets, or any combination of electromagnets and permanent magnets for directing, focusing, and shaping the electron beam. In some embodiments, electron optics 104 may include solenoids, quadrupoles, octupoles, etc., configured magnetically, electrostatically, or a combination thereof, to shape, focus, and direct the electron beam.

In addition, electron optics 104 may be configured for active control by computing system 130. In some embodiments, computing system 130 is communicatively coupled to electron optics 104. In some examples, current or voltage supplied to electron optic elements may be actively controlled based on command signals communicated from computing system 130 to electron optics 104. In another example, the position of a magnetic element (e.g., a permanent magnet, solenoid coil, etc.) may be manipulated by a positioning system (not shown) based on command signals communicated from computing system 130 to electron optics 104. In this manner, the focusing and directing of the stream of electrons 106 is achieved under the control of computing system 130 to achieve a stable stream of electrons 106 incident on anode material 111.

FIG. 1 depicts an arrangement of electron optics 104 in one embodiment. In the embodiment depicted in FIG. 1, electron optics 104 includes an alignment coil 114, a focusing objective lens 115, and a quadrupole lens 116. Electron beam source 103 emits an electron beam 106 having a cross-sectional shape that is approximately circular. Focusing lens 115 focuses the electron beam 106. In this manner, focusing objective lens 115 controls a size of the cross-sectional shape of electron beam 106 incident on anode 111. In the embodiment depicted in FIG. 1, computing system 130 is communicatively coupled to focusing objective lens 115. In one example, current or voltage supplied to electromagnetic elements of focusing objective lens 115 is actively controlled based on command signals 136 communicated from computing system 130 to focusing objective lens 115. In response, focusing objective lens 115 changes a size of the cross-sectional shape of electron beam 106 incident on anode 111 to achieve a desired size of the cross-sectional shape of electron beam 106 incident on anode 111.

In one embodiment, a quadrupole lens 116 changes the cross-sectional shape of electron beam 106 from approximately circular to an elongated shape. In this manner, quadrupole lens 116 controls the aspect ratio of the elongated cross-section of electron beam 106 incident on anode 111. In the embodiment depicted in FIG. 1, computing system 130 is communicatively coupled to quadrupole lens 116. In one example, current or voltage supplied to electromagnetic elements of quadrupole lens 116 is actively controlled based on command signals 137 communicated from computing system 130 to quadrupole lens 116. In response, quadrupole lens 116 changes the cross-sectional shape of electron beam 106 incident on anode 111 to achieve a desired elongated shape having a desired aspect ratio of electron beam 106 incident on anode 111.

Furthermore, in the embodiment depicted in FIG. 1, electron optics 104 includes beam alignment coil 114. Beam alignment coil 114 changes the direction of propagation of electron beam 106. In this manner, beam alignment coil 114 controls the angle of the electron beam 106 through focusing lens 115 to control the uniformity of the electron beam spot incident on anode 111. In the embodiment depicted in FIG. 1, computing system 130 is communicatively coupled to beam alignment coil 114. In one example, current or voltage supplied to electromagnetic elements of beam alignment coil 114 is actively controlled based on command signals 135 communicated from computing system 130 to beam alignment coil 114. In response, beam alignment coil 114 changes the angle of electron beam 106 through the focusing lens 115 to control the uniformity of the electron beam spot incident on anode 111.

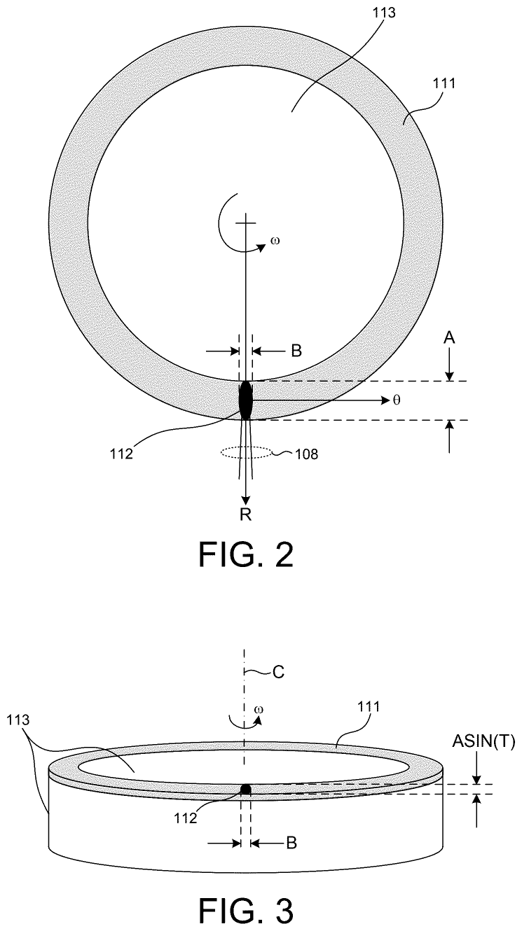

FIG. 2 is a simplified diagram illustrative of the incidence of electron beam 106 on anode material 111 as viewed from a direction aligned with electron beam 106. In some embodiments, beam alignment coil 114, focusing objective lens 115, and quadrupole lens 116 are independently controlled to generate an electron beam spot 112 incident on anode material 111. In the example depicted in FIG. 2, electron beam spot 112 is elongated in shape having a major axis aligned with the direction of maximum extent and a minor axis perpendicular to the major axis. The full width half maximum of the electron intensity along the major axis, A, divided by the full width half maximum of the electron intensity along the minor axis, B, is at least four. In some embodiments, dimension, B, is less than 60 micrometers. In some embodiments, dimension, B, is less than 40 micrometers. In one example, dimension A is approximately 400 micrometers and dimension B is approximately 40 micrometers. In this example, the aspect ratio of the elongated beam shape is approximately 10.

In a further aspect, electron optics 104 are controlled to shape electron beam 106 such that the major axis of the elongated shape of the electron beam spot 112 incident on anode material 111 is approximately aligned with a radial axis, R, extending radially from a center of rotation of rotary platen 113, and the minor axis of the elongated shape is approximately aligned with a tangential axis, θ, perpendicular to radial axis, R, at the center of the elecongated shape. Heat dissipates more readily in the radial direction because there is a large material volume of rotary platen 113 that is not bombarded with electrons, i.e., the portion of rotary platen 113 with a radius less than the inner radius of anode material 111. This portion of rotary platen 113 is cooled and acts as a large heat sink. Thus, heat generated by anode material 111 readily dissipates toward the center of rotary platen 113.

Conversely, heat generated by anode material 111 does not readily dissipate tangentially because the steady state temperature of anode material 111 is significantly higher than the inner portion of rotary platen 113. By spreading the electron beam energy over a larger dimension, i.e., along the major axis of the elongated shape of the electron beam spot 112, in the radial direction, heat is able to dissipate tangentially without generating an excessively high thermal gradient in the tangential direction. In this manner, the degradation rate of the anode material 111 is reduced for a given electron beam flux incident on the anode material 111.

In general, rotary platen 113 is fabricated from a material with high thermal conductivity that is generally compatible with commonly employed coolants, e.g., copper, chrome copper, aluminum, copper and aluminum alloys, etc.

In another further aspect, the stream of electrons is incident to a rotating anode material structure at a take-off angle of more than three degrees from normal incidence. Normal incidence is perpendicular to the surface of the rotating anode material structure. In some embodiments, take-off angle, T, is more than three degrees and up to twenty degrees. At these shallow take-off angles, high brightness X-Rays are collected across a larger dimension in the radial direction of the rotating anode surface compared to the tangential direction. This corresponds with the high aspect ratio electron beam spot 112 described with reference to FIG. 2. In this manner, high brightness X-Rays are collected across the major axis of the elongated electron beam spot 112 even though the electron beam 106 is distributed over a larger area in the radial direction.

As depicted in FIG. 1, the face of rotary platen 113 including anode material 111 is perpendicular to rotational axis, C. Furthermore, the axis of rotation, is tilted with respect to electron beam 106 by a take-off angle, T, of more than three degrees. Thus, electron beam 106 is incident to the face of anode material 111 at a take-off angle, T, with respect to an axis normal to the face of anode material 111.

FIG. 3 is a simplified diagram illustrative of the X-Rays collected from the high aspect ratio electron beam spot 112 as viewed from a direction aligned with X-Ray beam 108. In this embodiment, the length of the spot of the collected X-Rays in the tangential direction has a dimension, B, matching the dimension of the electron beam spot 112 in the tangential direction. However, the length of spot of the collected X-Rays in the radial direction has a dimension, A*sin (T).

In a preferred embodiment, dimension, A, is 400 micrometers, dimension, B, is 40 micrometers, and take-off angle, T, is approximately six degrees. In this embodiment, the shape of the collected X-Rays at the high aspect ratio electron beam spot 112 is approximately circular, with a diameter of 40 micrometers.

By bombarding anode material 111 with an electron beam having a high aspect ratio elongated cross section, beam power levels are increased beyond what is possible with low aspect ratio electron beam before reaching reliability limits induced by overheating of the anode material 111. Furthermore, by implementing a shallow take-off angle, an approximately circular shaped X-Ray beam is collected from the high aspect ratio elongated cross sectional area of X-Ray emission without loss of X-Ray brightness.

As illustrated by FIG. 3, a larger take-off angle allows collection of high brightness X-Rays with a circular beam shape from an electron beam having a larger aspect ratio elongated cross section. However, as the take-off angle approaches zero degrees, too many photons are absorbed and brightness decreases.

In the embodiment depicted in FIG. 1, computing system 130 is communicatively coupled to rotating anode subsystem 110. In one example, command signals 138 are communicated to rotating anode subsystem 110 from computing system 130 indicating a desired angular velocity of the rotating platen 113. In response, rotating anode subsystem 110 adjusts the angular velocity of the rotating platen 113 based on command signals 138.

In some embodiments, mechanical bearing based rotating anode subsystem 110 includes mechanical bearings and water cooling of the drive motor, rotary platen 113, and ferrofluidic seal. In some these embodiments, a mechanical bearing based rotating anode subsystem 110 is capable of rotational speeds up to 12,000 revolutions per minute.

In some embodiments, an air bearing based rotating anode subsystem 110 is capable of high rotational speeds without excessive frictional losses and heat generation. In some embodiments, rotating anode subsystem 110 is operable at any desired rotational speed from zero revolutions per minute to 40,000 revolutions per minute. For a platen 113 having a diameter of 100 millimeters, the tangential velocity of anode material 111 is operable at any desired linear speed from zero meters/second to 210 meters/second. In other embodiments, even higher rotational speeds, e.g., up to 100,000 revolutions per minute are contemplated within the scope of this patent document. In general, rotating anode subsystem 110 operates with a mechanical runout of less than 10 micrometers.

A high speed rotating anode reliably operating in high vacuum without producing excessive heat is enabled by a water cooled rotating platen supported by radial and thrust air bearings employing cascaded differential pumping. The air bearings allow for rotation at very high speeds with extremely low friction and much greater reliability compared to mechanical bearings. With reduced friction, a compact rotary motor provides sufficient torque to drive the rotating anode at high speed. Differential pumping provides a vacuum seal with significantly less viscous drag compared to conventional ferrofluidic seals without the risk of material contamination of the vacuum environment. With significantly less friction, heat generated in the rotating assembly is minimized, and stability of the rotating assembly during high speed operation is improved.

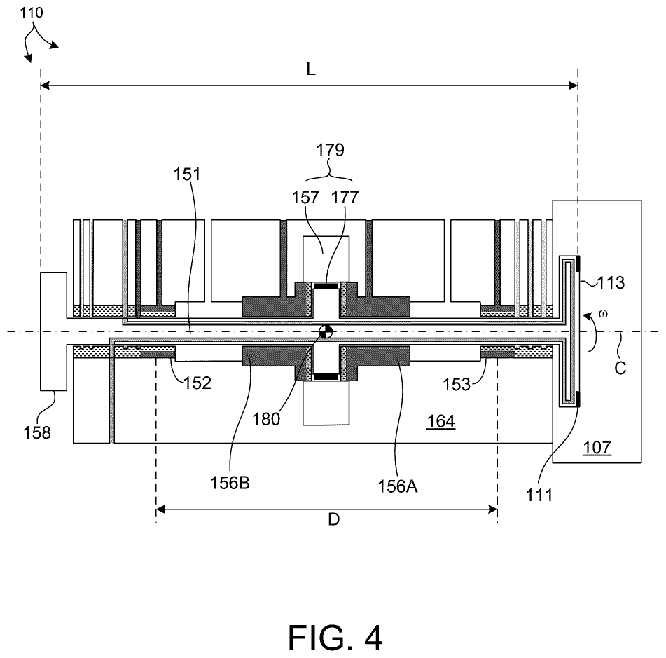

FIG. 4 depicts a cross-sectional view of aspects of rotating anode subassembly 110 depicted in FIG. 1 in one embodiment. As depicted in FIG. 4, rotating anode subassembly 110 includes rotary spindle shaft 151. One end of the rotary spindle shaft extends through an opening in a wall of vacuum chamber 107. Rotary platen 113 is attached to rotary spindle shaft 151 inside vacuum chamber 107. In this manner, rotary platen 113 rotates within vacuum chamber 107. Counterweight 158 is attached to the opposite end of rotary spindle 151. In some embodiments, rotary platen 113, counterweight 158, or both, are removably attached to rotary spindle shaft 151. However, in some other embodiments, rotary platen 113, counterweight 158, or both are permanently fixed to rotary spindle shaft 151. The rotating assembly, including rotary spindle shaft 151, platen 113, and counterweight 158, rotates about axis, C, at angular velocity, @.

Anode material 111 is disposed on a surface of rotary platen 113. In the embodiment depicted in FIG. 4, anode material 111 is disposed at the periphery of rotary platen 113 on the face of rotary platen 113 oriented perpendicular to axis, C. In the embodiment depicted in FIG. 4, rotary platen 113 is disk shaped. However, in other embodiments, different shapes, e.g., conical shapes, curved shapes, etc. may be contemplated. In this manner, anode material 111 may be optimally positioned with respect to the electron beam source. In some embodiments, the diameter of rotary platen 113 is greater than 50 millimeters. In some embodiments, the diameter of rotary platen 113 is approximately 100 millimeters. However, in general, rotary platen 113 may be any suitable diameter.

As depicted in FIG. 4, the rotating assembly is supported by radial air bearings 152 and 153, and thrust bearings 156A and 156B. Bearings 152, 153, and 156A-B are fixed to housing 164, and are coupled to a pressurized gas source, e.g., clean, dry, compressed air source. Pressurized clean, dry air is delivered to radial air bearings 152 and 153 and thrust bearings 156A and 156B. In a preferred embodiment, radial air bearings 152 and 153 and thrust bearings 156A-B are porous air bearings. However, in some other embodiments, any of radial air bearings 152 and 153 and thrust bearings 156A-B is a groove compensated air bearing.

Bearings 152, 153, and 156A-B allow free rotation of the rotating assembly about axis, C, but constrain all other degrees of freedom within very tight tolerances. Radial air bearings 152 and 153 exhibit a high stiffness in the direction perpendicular to rotational axis, C, of the rotary spindle shaft. In other words, radial air bearings 152 and 153 support a very large load in the direction perpendicular to rotational axis, C, of the rotary spindle shaft with very little deflection in the same direction. In one example, the maximum runout of the rotating assembly is less than two micrometers.

As depicted in FIG. 4, rotating anode subassembly 110 includes a rotary motor 179 disposed between radial air bearings 152 and 153. The rotary motor 179 includes a stator 159 mechanically coupled to housing 164 and a rotor 177 mechanically coupled rotary spindle shaft 151. The rotary motor 179 applies a rotational torque to the rotary spindle shaft 151 and drives the rotation of platen 113. In some embodiments, the rotary motor 179 is a brushless servo motor. In some of these embodiments, the brushless servo motor is ironless. However, in some other embodiments, the brushless servo motor includes an iron core to concentrate magnetic flux to realize higher torque with a smaller size motor.

Both rotary motor 179 and thrust bearings 156A-B are located between radial air bearings 152 and 153. By spacing radial air bearings 152 and 153 far apart and locating rotary motor 179 and thrust bearings 156A-B between radial air bearings 152 and 153, a very high bending stiffness of the rotating assembly, e.g., greater than 500,000 Newton-meters per radians is achieved. The high bending stiffness increases the mechanical stability of the rotating assembly during high speed operation, and thus decreases vibration at the location of impingement of the electron beam 106 on anode material 111.

In some embodiments, as depicted in FIG. 4, the spacing, D, between radial air bearings 152 and 153 is approximately 250 millimeters. However, in general, the spacing between radial air bearing 152 and 153 may be any suitable distance. In some embodiments, the distance, D, between radial air bearings 152 and 153 is greater than 80% of the total length, L, of the rotary spindle shaft.

As depicted in FIG. 4, the center of mass 180 of the rotating assembly is located close to the center of bending stiffness of the rotating assembly. In some embodiments, the center of mass 180 of the rotating assembly is within 5 centimeters of the center of bending stiffness of the rotating assembly. In some embodiments, the center of mass 180 of the rotating assembly is coincident with the center of bending stiffness of the rotating assembly. Furthermore, in some embodiments, rotary motor 179 is located within 5 centimeters of the center of mass 180 of the rotating assembly.

Radial air bearing 153 includes vacuum scavenged annular grooves at the interface with vacuum chamber 107 to minimize molecular flow from air bearing 153 to vacuum chamber 107. As depicted in FIG. 4, radial air bearing 153 includes annular grooves having a flow path to a vacuum source. The vacuum flow path evacuates the air flow leaking from the air film interface between the load bearing surface of radial air bearing 153 and rotary spindle shaft 151 before it reaches vacuum chamber 107. In addition, vacuum chamber 107 includes a molecular pump to remove any amount of air that reaches vacuum chamber 107.

As depicted in FIG. 4, coolant channels are located within rotary spindle shaft. The coolant flow through rotary platen 113 extracts heat from rotary platen 113 to maintain a constant temperature and minimize any geometrical distortions of rotary platen 113 induced by changing temperatures. The heat extracted from rotary platen 113 may be generated by a number of sources including 1) the interaction of the electron beam 106 with anode material 111, 2) heat generated by rotary motor 179 conducted to rotary platen 113 via rotary spindle shaft 151, and 3) heat generated by frictional losses at the bearing surfaces conducted to rotary platen 113 via rotary spindle shaft 151. Although coolant channels are depicted as channels located side by side along rotary spindle shaft 151, in some other embodiments, co-axial channels may be located along rotary spindle shaft 151; concentric with the axis of rotation, C.

As depicted in FIG. 1, X-Ray radiation emitted from electron beam spot 112 exits vacuum chamber 107 through X-Ray window 109 and passes through X-Ray optics 126 as X-Ray beam 108 propagates toward wafer 101. X-Ray optics 126 are configured to collect X-Ray emission from the spot of incidence of the stream of electrons 106 and anode material 111 and shape and direct incident X-Ray beam 108 to specimen 101.

In another aspect, X-Ray optics 126 are configured at specific collection angles to capture X-Ray emission in the desired energy band at peak intensity. In some embodiments, X-Ray optics 126 are designed to directly focus X-Ray radiation to the measurement target. When a high energy focused electron beam impinges upon an anode target, the stimulated X-Ray emission includes broadband Bremsstrahlung radiation and characteristic line emission (i.e., Kα, Kβ, Lα, Lβ, etc.). In some embodiments, X-Ray collection optics are oriented in such a way as to optimize X-Ray brightness by collecting X-Ray radiation over a range of collection angles.

In some examples, X-Ray optics 126 includes shielding, a monochromator, or both, to filter out Bremsstrahlung emission from X-Ray beam 108. In some examples, X-Ray optics 126 collimate or focus the X-Ray beam 108 onto inspection area 102 of specimen 101. However, in some embodiments, X-Ray optics do not collimate or focus the X-Ray beam 108 to avoid optical losses incurred by collimating and focusing optics. In some of these embodiments, X-Rays emitted from the rotating anode source with a circular cross section of approximately 40 micrometers in diameter propagate to wafer 101 without focusing and illuminate wafer 101 with an illumination spot size of approximately 300 micrometers in diameter at wafer 101.

In general, X-Ray optics 126 includes one or more X-Ray collimating mirrors, X-Ray apertures, X-Ray monochromators, and X-Ray beam stops, multilayer optics, refractive X-Ray optics, diffractive optics such as zone plates, or any combination thereof.

In some embodiments, advanced X-Ray optics such as polycapillary X-Ray optics, specular optics, or optics arranged in a Loxley-Tanner-Bowen configuration are employed to achieve high-brightness, small spot size illumination of a semiconductor specimen. For example, high intensity X-Ray beams can be transported and focused to spot sizes of less than 40 micrometers using specular X-Ray optics such as grazing incidence ellipsoidal mirrors, polycapillary optics such as hollow capillary X-Ray waveguides, multilayer optics, or crystalline optics such as a Loxley-Tanner-Bowen system.

In preferred embodiments, X-Ray optics 126 are multilayer optics. In some of these embodiments, multilayer optics are employed to monochromatize the X-Ray beam 108 to a spectral purity, δλ/λ, of less than 10⁻¹. This level of spectral purity is suitable for metrology technologies such as X-Ray reflectivity (XRR), X-Ray diffraction (XRD), and X-Ray fluorescence (XRF). In some other embodiments, crystal monochromators are employed to monochromatize the X-Ray beam 108 to a spectral purity, δλ/λ, of less than 10⁻⁶. This level of spectral purity is suitable for metrology technologies such as high resolution X-Ray diffraction (HRXRD).

X-Ray optics 126 may be configured for active control by computing system 130. In some embodiments, computing system 130 is communicatively coupled to X-Ray optics 126 (not shown). In one example, command signals communicated to X-Ray optics 126 from computing system 130 indicate a desired position of an optical element. The position of the optical element may be adjusted by a positioning system (not shown) based on the command signal. In this manner, the focusing and directing of the X-Ray beam 108 is achieved under the control of computing system 130 to achieve a stable illumination incident on specimen 101. In some examples, computing system 130 is configured to control the positioning and spot size of the X-Ray beam 108 incident on specimen 101. In some examples, computing system 130 is configured to control illumination properties of the X-Ray beam 108 (e.g., intensity, polarization, spectrum, etc.).

In the embodiment depicted in FIG. 1, the X-Ray illumination source provides high brightness X-Ray illumination delivered to a specimen 101 over an inspection area 102. X-Ray detector 123 collects X-Ray radiation 122 scattered from specimen 101 in response to the incident X-Ray illumination and generates output signals 124 indicative of properties of specimen 101 that are sensitive to the incident X-Ray radiation. Scattered X-Rays 122 are collected by X-Ray detector 123 while specimen positioning system 140 locates and orients specimen 101 to produce angularly resolved scattered X-Rays. In some embodiments, any other particles produced during the interaction such as photoelectrons, X-Rays produced through fluorescence, or ions may also be detected.

As depicted in FIG. 1, the X-Ray illumination source is maintained in a vacuum environment maintained within vacuum chamber 120. In some embodiments, vacuum less than 1e-8 torr is maintained within vacuum chamber 120. X-Ray emission passes through flight tube 105 as the stream of electrons 106 propagates from electron beam source 103 to anode material 111. Flight tube 105 is also maintained in a vacuum environment. As depicted in FIG. 1, flight tube 105 is coupled to vacuum chamber 107 housing rotary platen 113. Vacuum chamber 107 is also maintained in a vacuum environment. X-Rays pass through vacuum window 109 as the X-Rays propagate from anode material 111 toward X-Ray optics 126. Vacuum window 109 may be constructed of any suitable material that is substantially transparent to X-Ray radiation (e.g., Kapton, Beryllium, etc.).

In a further aspect, metrology system 100 includes X-Ray sensors in the X-Ray optical path to measure X-Ray source spot size and uniformity. In a further aspect, metrology system 100 includes computing system 130 configured to control one or more elements of electron optics 104, electron beam source 103, or both, to calibrate the high brightness X-Ray illumination system to achieve a desired X-Ray illumination spot size and uniformity to maximize the ratio of power loading of anode material 111 divided by incident electron beam current.

In the embodiment depicted in FIG. 1, metrology system 100 includes an assembly 128 including a pin hole structure and a PIN diode based photodetector mounted as close to the incidence of electron beam 106 with anode material 111, i.e., the X-Ray source. In addition, metrology system 100 includes an X-Ray imaging device 125, e.g., an X-Ray sensitive camera 125, that images the X-Ray source. X-Ray imaging device 125 is located in the X-Ray beam path downstream from the pin hole. In the embodiment depicted in FIG. 1, X-Ray imaging device 125 is coupled to motion stage 121, which causes the X-Ray imaging device 125 to be inserted in the X-Ray beam path during calibration and removed from the X-Ray beam path during measurements. The images 127 collected by X-Ray camera 125 are received by computing system 130. Computing system 130 generates command signals communicated to electron beam source 103, electron optics 104, or both, based on images 127. In response, the physical configuration of electron beam source 103, electron optics 104, or both, is adjusted to optimize the X-Ray spot profile slope, uniformity, and spot size. In some embodiments, adjustments to the position of the cathode motors, adjustments to currents applied to the electron optics, or both are implemented to optimize X-Ray spot profile slope, uniformity, and spot size.

The coincidence of anode material 111 and the stream of electrons 106 produces X-Ray emission 108 incident on inspection area 102 of specimen 101. In some embodiments, the X-Ray illumination source collects K-shell emission, L-shell emission, or a combination thereof, from the anode material. In some embodiments, it is preferred to have a X-Ray source photon energy in a range from 10 keV to 25 keV to penetrate through a silicon wafer with suitable transmission efficiency for Transmission Small Angle X-Ray Scattering (T-SAXS) based semiconductor metrology applications such as critical dimension and overlay metrology on patterned silicon wafers.

In some embodiments, the distance between specimen 101 and anode material 111 is lengthy (e.g., greater than one meter). In these embodiments, air present in the beam path introduces undesirable beam scattering. Hence, in some embodiments it is preferred to propagate X-Ray beam 108 through an evacuated flight tube from the X-Ray illumination source to specimen 101.

In some embodiments, the X-Ray detector 123 is maintained in the same atmospheric environment as specimen 101 (e.g., gas purge environment). However, in some embodiments, the distance between specimen 101 and X-Ray detector 123 is lengthy (e.g., greater than one meter). In these embodiments, air present in the beam path introduces undesirable beam scattering, especially when the X-Ray illumination source is configured to generate hard X-Rays (e.g., photon energy greater than 5 keV). Hence in some embodiments, the X-Ray detector 123 is maintained in a localized, vacuum environment separated from the specimen (e.g., specimen 101) by a vacuum window.

In some embodiments, it is desirable to maintain the X-Ray illumination beam 108, specimen 101, the collection beam 122, and detector 123 in an evacuated environment to minimize absorption of X-Rays. This is especially desirable if the X-Ray illumination source is configured to generate soft X-Rays (e.g., photon energy less than 5 keV).

In another further aspect, the high brightness, rotating anode based X-Ray illumination source described herein is oriented at any desired orientation relative to the specimen under measurement. In some embodiments, such as the embodiment depicted in FIG. 1, the electron beam propagates in a horizontal direction, and the X-Ray beam line propagates in a vertical direction. However, in general, electron beam propagation and X-Ray beam line propagation can be oriented in any suitable configuration.

By way of non-limiting example, the X-Ray metrology system 100 illustrated in FIG. 1 is configured as a transmission small angle X-Ray scatterometer (TSAXS). However, in general, an X-Ray metrology system employing a rotating anode based X-Ray illumination source as described herein may employ any one or more of the following metrology techniques: transmission small angle X-Ray scattering (TSAXS), wide angle X-Ray scattering (WAXS), X-Ray reflectometry (XRR), grazing incidence X-Ray reflectometry (GXR), X-Ray diffraction (XRD), grazing incidence X-Ray diffraction (GIXRD), high resolution X-Ray diffraction (HRXRD), X-Ray photoelectron spectroscopy (XPS), X-Ray fluorescence (XRF), total reflection X-Ray fluorescence (TXRF), grazing incidence X-Ray fluorescence (GIXRF), X-Ray tomography, X-Ray microscopy, X-Ray imaging, X-Ray ellipsometry, and hard X-Ray photoemission spectrometry (HXPS).

X-Ray metrology tool 100 also includes computing system 130 employed to acquire signals 124 generated by X-Ray detector 123 and determine properties of the specimen based at least in part on the acquired signals. As illustrated in FIG. 1, computing system 130 is communicatively coupled to X-Ray detector 123. In one example, X-Ray detector 123 is an X-Ray spectrometer and measurement data 124 includes an indication of the measured spectral response of the specimen based on one or more sampling processes implemented by the X-Ray spectrometer. Computing system 130 is configured to build models of the specimen, create X-Ray simulations based upon the models, and analyze the simulations and signals 124 received from X-Ray detector 123 to determine one or more characteristics of the sample (e.g., a value of a parameter of interest 180 of a structure under measurement).

In a further embodiment, computing system 130 is configured to access model parameters in real-time, employing Real Time Critical Dimensioning (RTCD), or it may access libraries of pre-computed models for determining a value of at least one specimen parameter value associated with the specimen 101. In general, some form of CD-engine may be used to evaluate the difference between assigned CD parameters of a specimen and CD parameters associated with the measured specimen. Exemplary methods and systems for computing specimen parameter values are described in U.S. Pat. No. 7,826,071, issued on Nov. 2, 2010, to KLA-Tencor Corp., the entirety of which is incorporated herein by reference.

In one example, measurement data 124 includes an indication of the X-Rays 122 scattered from the specimen. Based on the distribution of the measured X-Ray response on the surface of detector 123, the location and area of incidence of X-Ray beam 108 on specimen 101 is determined by computing system 130. In one example, pattern recognition techniques are applied by computing system 130 to determine the location and area of incidence of X-Ray beam 108 on specimen 101 based on measurement data 124. In response computing system 130 generates command signals to any of electron beam source 103, electron optics 104, and X-Ray optics 126 to redirect and reshape incident X-Ray illumination beam 108.

In another aspect, X-Ray measurements of a particular inspection area are performed at a number of different out of plane orientations. This increases the precision and accuracy of measured parameters and reduces correlations among parameters by extending the number and diversity of data sets available for analysis to include a variety of large-angle, out of plane orientations. Measuring specimen parameters with a deeper, more diverse data set also reduces correlations among parameters and improves measurement accuracy.

As illustrated in FIG. 1, X-Ray metrology tool 100 includes a specimen positioning system 140 configured to both align specimen 101 and orient specimen 101 over a large range of out of plane angular orientations with respect the X-Ray illumination source. In other words, specimen positioning system 140 is configured to rotate specimen 101 over a large angular range about one or more axes of rotation aligned in-plane with the surface of specimen 101. In some embodiments, specimen positioning system 140 is configured to rotate specimen 101 within a range of at least 90 degrees about one or more axes of rotation aligned in-plane with the surface of specimen 101. In some embodiments, specimen positioning system is configured to rotate specimen 101 within a range of at least 60 degrees about one or more axes of rotation aligned in-plane with the surface of specimen 101. In some other embodiments, specimen positioning system is configured to rotate specimen 101 within a range of at least one degree about one or more axes of rotation aligned in-plane with the surface of specimen 101. In this manner, angle resolved measurements of specimen 101 are collected by X-Ray metrology system 100 over any number of locations on the surface of specimen 101. In one example, computing system 130 communicates command signals to motion controller 145 of specimen positioning system 140 that indicate the desired position of specimen 101. In response, motion controller 145 generates command signals to the various actuators of specimen positioning system 140 to achieve the desired positioning of specimen 101. By way of non-limiting example, a specimen positioning system may include any combination of a hexapod, linear, and angular stages.

By way of non-limiting example, as illustrated in FIG. 1, specimen positioning system 140 includes an edge grip chuck 141 to fixedly attach specimen 101 to specimen positioning system 140. A rotational actuator 142 is configured to rotate edge grip chuck 141 and the attached specimen 101 with respect to a perimeter frame 143. In the depicted embodiment, rotational actuator 142 is configured to rotate specimen 101 about the x-axis of the coordinate system 146 illustrated in FIG. 1. As depicted in FIG. 1, a rotation of specimen 101 about the z-axis is an in plane rotation of specimen 101. Rotations about the x-axis and the y-axis (not shown) are out of plane rotations of specimen 101 that effectively tilt the surface of the specimen with respect to the metrology elements of metrology system 100. Although it is not illustrated, a second rotational actuator is configured to rotate specimen 101 about the y-axis. A linear actuator 144 is configured to translate perimeter frame 143 in the x-direction. Another linear actuator (not shown) is configured to translate perimeter frame 143 in the y-direction. In this manner, every location on the surface of specimen 101 is available for measurement over a range of out of plane angular positions. For example, in one embodiment, a location of specimen 101 is measured over several angular increments within a range of −45 degrees to +45 degrees with respect to the normal orientation of specimen 101.

The large, out of plane, angular positioning capability of specimen positioning system 140 expands measurement sensitivity and reduces correlations between parameters. For example, in a normal orientation, SAXS is able to resolve the critical dimension of a feature, but is largely insensitive to sidewall angle and height of a feature. However, collecting measurement data over a broad range of out of plane angular positions enables the collection of measurement data associated with a number of diffraction orders. This enables the sidewall angle and height of a feature to be resolved. In addition, other features such as rounding or any other shapes associated with advanced structures can be resolved.

A X-Ray metrology tool employing a rotating anode based X-Ray illumination source as described herein enables increased measurement sensitivity and throughput due to the high brightness and short wavelength radiation (e.g., photon energy greater than 500 eV) generated by the source. By way of non-limiting example, the X-Ray metrology tool is capable of measuring geometric parameters (e.g., pitch, critical dimension (CD), side wall angle (SWA), line width roughness (LWR), and line edge roughness (LER)) of structures smaller than 10 nanometers. In addition, the high energy nature of X-Ray radiation penetrates optically opaque thin films, buried structures, high aspect ratio structures, and devices including many thin film layers.

A X-Ray metrology system employing a high brightness X-Ray illumination source as described herein may be used to determine characteristics of semiconductor structures. Exemplary structures include, but are not limited to, low-dimensional structures such as nanowires or graphene, sub 10 nm structures, thin films, lithographic structures, memory structures such as DRAM, DRAM 4F2, FLASH and high aspect ratio memory structures. Exemplary structural characteristics include, but are not limited to, geometric parameters such as line edge roughness, line width roughness, pore size, pore density, side wall angle, profile, film thickness, critical dimension, pitch, and material parameters such as electron density, crystalline grain structure, morphology, orientation, stress, and strain.

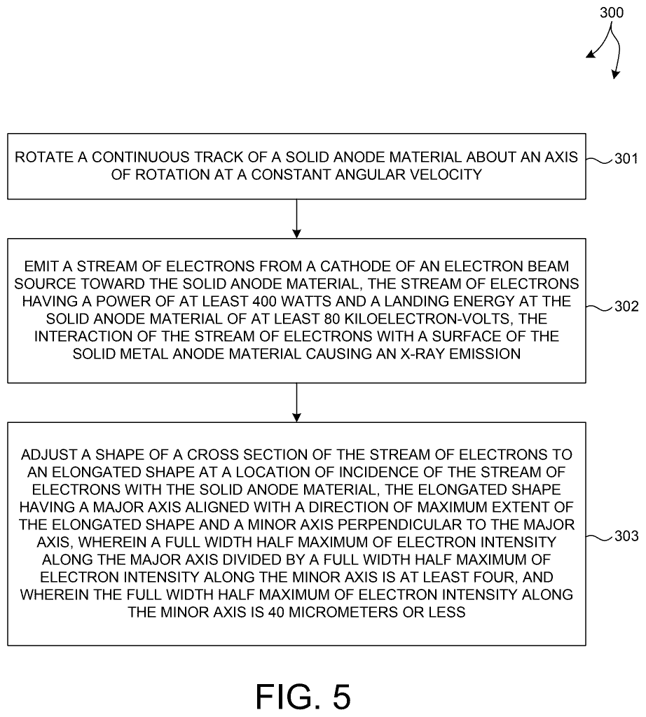

FIG. 5 illustrates a method 300 suitable for implementation by the X-Ray metrology system 100 of the present invention. In one aspect, it is recognized that any data processing elements of method 300 may be carried out via a pre-programmed algorithm executed by one or more processors of computing system 130. While the following description is presented in the context of X-Ray metrology system 100, it is recognized herein that the particular structural aspects of X-Ray metrology system 100 do not represent limitations and should be interpreted as illustrative only.

In block 301, a continuous track of a solid anode material is rotated about an axis of rotation at a constant angular velocity.

In block 302, a stream of electrons is emitted from a cathode of an electron beam source and accelerated toward the solid, rotating anode material. The stream of electrons has a power of at least 400 Watts and an accelerating voltage of at least 80 kiloelectron-volts. The interaction of the stream of electrons with a surface of the solid rotating anode material excites an X-Ray emission.

In block 303, a shape of a cross section of the stream of electrons is adjusted to an elongated shape at a location of incidence of the stream of electrons with the solid anode material. The elongated shape has a major axis aligned with a direction of maximum extent of the elongated shape and a minor axis perpendicular to the major axis. A full width half maximum of electron intensity along the major axis divided by a full width half maximum of electron intensity along the minor axis is at least four. The full width half maximum of electron intensity along the minor axis is 40 micrometers or less.

It should be recognized that the various steps described throughout the present disclosure may be carried out by a single computer system 130 or, alternatively, a multiple computer system 130. Moreover, different subsystems of the metrology system 100, such as the specimen positioning system 140, may include a computer system suitable for carrying out at least a portion of the steps described herein. Therefore, the aforementioned description should not be interpreted as a limitation on the present invention but merely an illustration. Further, the one or more computing systems 130 may be configured to perform any other step(s) of any of the method embodiments described herein.

In addition, the computer system 130 may be communicatively coupled to the X-Ray detector 123, electron optics 104, X-Ray optics 126, electron beam source 103, rotary anode subsystem 110, and specimen positioning system 140 in any manner known in the art. For example, the one or more computing systems 130 may be coupled to computing systems associated with X-Ray detector 123, electron optics 104, X-Ray optics 126, electron beam source 103, rotary anode subsystem 110, and specimen positioning system 140, respectively. In another example, any of X-Ray detector 123, electron optics 104, X-Ray optics 126, electron beam source 103, rotary anode subsystem 110, and specimen positioning system 140 may be controlled directly by a single computer system coupled to computer system 130.

The computer system 130 of the X-Ray metrology systems 100 may be configured to receive and/or acquire data or information from the subsystems of the system (e.g., X-Ray detector 123, electron optics 104, X-Ray optics 126, electron beam source 103, rotary anode subsystem 110, and specimen positioning system 140, and the like) by a transmission medium that may include wireline, optical fiber, and/or wireless portions. In this manner, the transmission medium may serve as a data link between the computer system 130 and other subsystems of the system 100.

Computer system 130 of the metrology system 100 may be configured to receive and/or acquire data or information (e.g., measurement results, modeling inputs, modeling results, etc.) from other systems by a transmission medium that may include wireline and/or wireless portions. In this manner, the transmission medium may serve as a data link between the computer system 130 and other systems (e.g., memory on-board metrology system 100, external memory, or external systems). For example, the computing system 130 may be configured to receive measurement data (e.g., output signals 124) from a storage medium (i.e., memory 132) via a data link. For instance, spectral results obtained using a spectrometer of X-Ray detector 123 may be stored in a permanent or semi-permanent memory device (e.g., memory 132). In this regard, the spectral results may be imported from on-board memory or from an external memory system. Moreover, the computer system 130 may send data to other systems via a transmission medium. For instance, specimen parameter values 180 determined by computer system 130 may be stored in a permanent or semi-permanent memory device. In this regard, measurement results may be exported to another system.

Computing system 130 may include, but is not limited to, a personal computer system, cloud based computing system, mainframe computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, optical fiber, or wireless transmission link. For example, as illustrated in FIG. 1, program instructions stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In some embodiments, X-Ray metrology as described herein is implemented as part of a fabrication process tool. Examples of fabrication process tools include, but are not limited to, lithographic exposure tools, film deposition tools, implant tools, and etch tools. In this manner, the results of X-Ray measurements are used to control a fabrication process. In one example, X-Ray measurement data collected from one or more targets is sent to a fabrication process tool. The X-Ray data is analyzed and the results used to adjust the operation of the fabrication process tool.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including critical dimension applications and overlay metrology applications. However, such terms of art do not limit the scope of the term “metrology system” as described herein. In addition, the metrology systems described herein may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the measurement techniques described herein.

Various embodiments are described herein for a semiconductor processing system (e.g., an inspection system or a lithography system) that may be used for processing a specimen. The term “specimen” is used herein to refer to a wafer, a reticle, packaging components, interposer components, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, XRF disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A high brightness, rotating anode X-Ray source comprising:
a rotating support structure including a continuous track of a solid anode material rotating about an axis of rotation at a constant angular velocity;
a rotational actuator coupled to the rotating anode support structure, wherein the rotational actuator rotates the rotating anode support structure at the constant angular velocity;
an electron beam source emitting a stream of electrons toward the solid anode material from a cathode of the electron beam source, the stream of electrons having a power of at least 400 Watts and a landing energy at the solid anode material of at least 80 kiloelectron-volts, the interaction of the stream of electrons with the solid anode material causing an X-Ray emission; and
one or more electron optical elements disposed along a path of the stream of electrons from the cathode to the solid anode material, wherein the one or more electron optical elements adjust a shape of an electron beam intensity cross section of the stream of electrons to an elongated shape at a location of incidence of the stream of electrons with the solid anode material, the elongated shape having a major axis aligned with a direction of maximum extent of the elongated shape and a minor axis perpendicular to the major axis, wherein a full width half maximum of electron intensity along the major axis divided by a full width half maximum of electron intensity along the minor axis is at least four, and wherein the full width half maximum of electron intensity along the minor axis is 40 micrometers or less.

2. The high brightness, rotating anode X-Ray source of claim 1, wherein the stream of electrons is incident to the surface of the solid anode material at a take-off angle of more than three degrees from a normal to the surface of the solid anode material.

3. The high brightness, rotating anode X-Ray source of claim 2, wherein a shape of the X-Ray radiation extracted over the location of incidence of the stream of electrons with the solid anode material as viewed along a direction of extraction of the X-Ray radiation is approximately circular.

4. The high brightness, rotating anode X-Ray source of claim 1, wherein the stream of electrons is incident to the surface of the solid anode material at a take-off angle in a range between three degrees and twenty degrees from a normal to the surface of the solid anode material.

5. The high brightness, rotating anode X-Ray source of claim 1, further comprising:
one or more bearings disposed around a rotary spindle shaft coupled to the rotating support structure, the one or more bearings configured to support a load in a direction perpendicular to the axis of rotation and support a load in a direction parallel to the axis of rotation, wherein the one or more bearings are mechanical bearings, air bearings, or magnetic bearings.

6. The high brightness, rotating anode X-Ray source of claim 1, the rotating support structure including one or more fluidic channels through which a cooling fluid is circulated.

7. The high brightness, rotating anode X-Ray source of claim 1, further comprising:
one or more sensors in a path of the X-Ray emission extracted from the location of incidence of the stream of electrons with the solid anode material, the one or more sensors generating signals indicative of a X-Ray source spot size, a X-Ray source spot uniformity, or both; and
a computing system configured to:
receive the signals indicative of the X-Ray source spot size, the X-Ray source spot uniformity, or both; and
communicate control command signals to the electron beam source, the one or more electron optical elements, or both, that cause the electron beam source, the one or more electron optical elements, or both, to adjust the X-Ray source spot size, the X-Ray source spot uniformity, or both, to achieve a desired X-Ray source spot size, a desired X-Ray source spot uniformity, or both.

8. A metrology system comprising:
a high brightness, rotating anode X-Ray source configured to illuminate a measurement area of a specimen with an incident X-Ray beam, the high brightness, rotating anode X-Ray source comprising:
a rotating support structure including a continuous track of a solid anode material rotating about an axis of rotation at a constant angular velocity;
a rotational actuator coupled to the rotating anode support structure, wherein the rotational actuator rotates the rotating anode support structure at the constant angular velocity;
an electron beam source emitting a stream of electrons toward the solid anode material from a cathode of the electron beam source, the stream of electrons having a power of at least 400 Watts and a landing energy at the solid anode material of at least 80 kiloelectron-volts, the interaction of the stream of electrons with a surface of the solid anode material causing an X-Ray emission; and
one or more electron optical elements disposed along a path of the stream of electrons from the cathode to the solid anode material, wherein the one or more electron optical elements adjust a shape of a cross section of the stream of electrons to an elongated shape at a location of incidence of the stream of electrons with the solid anode material, the elongated shape having a major axis aligned with a direction of maximum extent of the elongated shape and a minor axis perpendicular to the major axis, wherein a full width half maximum of electron intensity along the major axis divided by a full width half maximum of electron intensity along the minor axis is at least four, and wherein the full width half maximum of electron intensity along the minor axis is 40 micrometers or less;
at least one X-Ray optical element configured to collect an amount of the X-Ray emission from the location of incidence of the stream of electrons with the solid anode material, the amount of the X-Ray emission comprising the incident X-Ray beam; and
an X-Ray detector configured to receive radiation from the specimen in response to the incident X-Ray beam and generate signals indicative of a first property of the specimen.

9. The metrology system of claim 8, wherein the X-Ray based metrology system is a small angle X-Ray scatterometer configured to perform measurements in a transmissive mode.

10. The metrology system of claim 9, wherein the measurements are critical dimension measurement, overlay measurements, or both.

11. The metrology system of claim 8, wherein the metrology system is configured as any of a transmission small angle X-Ray scatterometry system, a wide angle X-Ray scatterometry system, a X-Ray reflectometry system, a grazing incidence X-Ray reflectometry system, a X-Ray diffractometry system, a grazing incidence X-Ray diffractometry system, a high resolution X-Ray diffractometry system, a X-Ray photoelectron spectrometry system, a X-Ray fluorescence metrology system, a total reflection X-Ray fluorescence metrology system, a grazing incidence X-Ray fluorescence metrology system, a X-Ray tomography system, a X-Ray ellipsometry system, and a hard X-Ray photoemission spectrometry system.

12. The metrology system of claim 8, wherein the stream of electrons is incident to the surface of the solid anode material at a take-off angle of more than three degrees from a normal to the surface of the solid anode material.

13. The metrology system of claim 12, wherein a shape of the X-Ray radiation extracted over the location of incidence of the stream of electrons with the solid anode material as viewed along a direction of extraction of the X-Ray radiation is approximately circular.

14. The metrology system of claim 8, wherein the stream of electrons is incident to the surface of the solid anode material at a take-off angle in a range between three degrees and twenty degrees from a normal to the surface of the solid anode material.

15. The metrology system of claim 8, further comprising:
one or more bearings disposed around a rotary spindle shaft coupled to the rotating support structure, the one or more bearings configured to support a load in a direction perpendicular to the axis of rotation and support a load in a direction parallel to the axis of rotation, wherein the one or more bearings are mechanical bearings, air bearings, or magnetic bearings.

16. The metrology system of claim 8, further comprising:
one or more sensors in a path of the X-Ray emission extracted from the location of incidence of the stream of electrons with the solid anode material beam, the one or more sensors generating signals indicative of a X-Ray source spot size, a X-Ray source spot uniformity, both; and
a computing system configured to:
receive the signals indicative of the X-Ray source spot size, the X-Ray source spot uniformity, both; and
communicate control command signals to the electron beam source, the one or more electron optical elements, or both, that cause the electron beam source, the one or more electron optical elements, or both, to adjust the X-Ray source spot size, the X-Ray source spot uniformity, or both, to achieve a desired X-Ray source spot size, a desired X-Ray source spot uniformity, or both.

17. A method comprising:
rotating a continuous track of a solid anode material about an axis of rotation at a constant angular velocity;
emitting a stream of electrons from a cathode of an electron beam source toward the solid anode material, the stream of electrons having a power of at least 400 Watts and a landing energy at the solid anode material of at least 80 kiloelectron-volts, the interaction of the stream of electrons with a surface of the solid anode material causing an X-Ray emission; and
adjusting a shape of a cross section of the stream of electrons to an elongated shape at a location of incidence of the stream of electrons with the solid anode material, the elongated shape having a major axis aligned with a direction of maximum extent of the elongated shape and a minor axis perpendicular to the major axis, wherein a full width half maximum of electron intensity along the major axis divided by a full width half maximum of electron intensity along the minor axis is at least four, and wherein the full width half maximum of electron intensity along the minor axis is 40 micrometers or less.

18. The method of claim 17, wherein the stream of electrons is incident to the surface of the solid anode material at a take-off angle of more than three degrees from a normal to the surface of the solid anode material.

19. The method of claim 17, further comprising:
generating signals indicative of a X-Ray source spot size, a X-Ray source spot uniformity, or both; and
adjusting the shape of the cross section of the stream of electrons to achieve a desired X-Ray source spot size, a desired X-Ray source spot uniformity, or both.

20. The method of claim 17, further comprising:
collecting an amount of the X-Ray emission from the location of incidence of the stream of electrons with the solid anode material, the amount of the X-Ray emission comprising an incident X-Ray beam;
illuminating a measurement area of a specimen with the incident X-Ray beam;
detecting radiation from the specimen in response to the incident X-Ray beam; and
generating signals indicative of a first property of the specimen based on the detected radiation.
